(19) United States
(12) Patent Application Publication
(10) Pub. No.: US 2026/0228876 A1
(43) Pub. Date: Aug. 6, 2026

(54) METHOD AND SYSTEM FOR IDENTIFYING A CENTER OF A PATTERN USING AUTOMATIC THRESHOLDING

(71) Applicant: ASML NETHERLANDS B.V., Veldhoven (NL)

(72) Inventor: Yifei MENG, San Jose, CA (US)

(73) Assignee: ASML NETHERLANDS B.V., Veldhoven (NL)

(21) Appl. No.: 19/150,552

(22) PCT Filed: Jan. 19, 2024
(86) PCT No.: PCT/EP2024/051199

§ 371 Date: Jul. 24, 2025

Related U.S. Application Data
(60) Provisional application No. 63/445,247, filed on Feb. 13, 2023.

(51) Int. Cl. G06T 7/00; G06T 7/66

(52) U.S. Cl. CPC G06T 7/0004; G06T 7/66; G06T 2207/10061; G06T 2207/30148

(57) ABSTRACT

A method for selecting a threshold value for processing an image to determine characteristics of a pattern. The method includes accessing an image representation of a pattern and generating multiple two-dimensional (2D) profiles of a feature of the pattern using different threshold values, wherein each 2D profile of the 2D profiles corresponds to a respective threshold value. The 2D profiles are evaluated to determine a KPI value of the 2D profiles and a specified threshold value from a range of threshold values is selected based on the evaluation of the 2D profiles.

### CROSS-REFERENCE TO RELATED APPLICATIONS

This application claims priority of U.S. application 63/445,247 which was filed on 13 Feb. 2023 and which is incorporated herein in its entirety by reference.

### TECHNICAL FIELD

The embodiments provided herein relate to semiconductor manufacturing, and more particularly to semiconductor metrology and inspection.

### BACKGROUND

A lithographic apparatus is a machine that applies a desired pattern onto a target portion of a substrate. The lithographic apparatus can be used, for example, in the manufacture of integrated circuits (ICs). For example, an IC chip in a smart phone, can be as small as a person's thumbnail, and may include over 2 billion transistors. Making an IC is a complex and time-consuming process, with circuit components in different layers and including hundreds of individual steps. Errors in even one step have the potential to result in problems with the final IC and can cause device failure. High process yield and high wafer throughput can be impacted by the presence of defects.

Metrology processes are used at various steps during a patterning process to monitor and/or control the process. For example, metrology processes are used to measure one or more characteristics of a substrate, such as a relative location (e.g., registration, overlay, alignment, etc.) or dimension (e.g., line width, critical dimension (CD), thickness, etc.) of features formed on the substrate during the patterning process or stochastic variation, such that, for example, the performance of the patterning process can be determined from the one or more characteristics. If the one or more characteristics are unacceptable (e.g., out of a predetermined range for the characteristic(s)), one or more variables of the patterning process may be designed or altered, e.g., based on the measurements of the one or more characteristics, such that substrates manufactured by the patterning process have an acceptable characteristic(s).

### BRIEF SUMMARY

In some embodiments, there is provided a method for automatically selecting a threshold value in processing an image to determine a metrology characteristics of a pattern. The method includes: accessing an image representation of a pattern; generating multiple two-dimensional (2D) profiles of a first feature of the pattern by processing the image representation using different threshold values, wherein each 2D profile of the 2D profiles corresponds to a respective threshold value; evaluating the 2D profiles; and selecting a specified threshold value of the threshold values based on the evaluating.

In some embodiments, there is provided a method for determining a center of a feature of a pattern by selecting a threshold value for processing an image representative of the pattern. The method includes: accessing an image representation representative of a pattern; iteratively thresholding the image representation using different threshold values to generate multiple 2D profiles of a first feature of the pattern, wherein each 2D profile of the 2D profiles corresponds to a respective threshold value; selecting a specified threshold value of the threshold values based on a performance indicator associated with the 2D profiles; and determining a center of the first feature using a 2D profile generated using the specified threshold value.

In some embodiments, there is provided a non-transitory computer readable medium having instructions that, when executed by a computer, cause the computer to execute a method of any of the above embodiments.

In some embodiments, there is provided an apparatus includes a memory storing a set of instructions and a processor configured to execute the set of instructions to cause the apparatus to perform a method of any of the above embodiments.

### BRIEF DESCRIPTION OF THE DRAWINGS

Embodiments will now be described, by way of example only, with reference to the accompanying drawings in which:

FIG. 1 is a schematic diagram illustrating an exemplary electron beam inspection (EBI) system, according to an embodiment.

FIG. 2 is a schematic diagram of an exemplary electron beam tool, according to an embodiment.

FIG. 3 depicts a schematic representation of holistic lithography, representing a cooperation between three technologies to optimize semiconductor manufacturing, according to an embodiment.

FIG. 4 is a block diagram of a system for automatically selecting a threshold value for processing an image of a pattern to determine an attribute of a feature, consistent with various embodiments.

FIG. 5 is a flow diagram of a method for automatically selecting a threshold value for processing an image of a pattern to determine an attribute of a feature, consistent with various embodiments.

FIG. 6 is a flow diagram of a method for determining an overlay error between features of a pattern using automatic thresholding, consistent with various embodiments.

FIGS. 7A-7D illustrate various geometrical attributes that may be used in determining a key performance indicator (KPI) of a two-dimensional (2D) profile of a feature, consistent with various embodiments.

FIGS. 8A-8N illustrate various KPIs associated with a 2D profile, consistent with various embodiments.

FIG. 9 is a block diagram of an example computer system, according to an embodiment.

Embodiments will now be described in detail with reference to the drawings, which are provided as illustrative examples so as to enable those skilled in the art to practice the embodiments. Notably, the figures and examples below are not meant to limit the scope to a single embodiment, but other embodiments are possible by way of interchange of some or all of the described or illustrated elements. Wherever convenient, the same reference numbers will be used throughout the drawings to refer to same or like parts. Where certain elements of these embodiments can be partially or fully implemented using known components, only those portions of such known components that are necessary for an understanding of the embodiments will be described, and detailed descriptions of other portions of such known components will be omitted so as not to obscure the description of the embodiments. In the present specification, an embodiment showing a singular component should not be considered limiting; rather, the scope is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the scope encompasses present and future known equivalents to the components referred to herein by way of illustration.

### DETAILED DESCRIPTION

A lithographic apparatus is a machine that applies a desired pattern onto a target portion of a substrate. This process of transferring the desired pattern to the substrate is called a patterning process. The patterning process can include a patterning step to transfer a pattern from a patterning device (such as a mask) to the substrate. Various variations (e.g., variations in the patterning process or the lithographic apparatus) can potentially limit lithography implementation for semiconductor high volume manufacturing (HVM). High resolution images of a substrate, such as images obtained using a scanning electron microscope (SEM), may be inspected for determining any defects in the patterning process. For example, the images may be inspected for determining an overlay between features of a pattern. To determine the overlay, a position of the features may have to be determined. For example, to determine the overlay of a feature, such as a via (e.g., a hole), with another feature, determining a center of the via accurately is an important step.

Conventional techniques employ various methods for determining a position of a feature (e.g., a center of a hole) in a pattern. For example, one method segments the SEM image with a user input threshold and counts the via blob centers from the binary image after segmentation. However, the conventional techniques have a problem. For example, when there is a significant overlay, due to electron signal interference from another layer in the pattern, a gray level profile of the hole can be asymmetric, causing a location of a middle point of the profile (e.g., a center of a hole) very sensitive to the threshold selection, which affects the overlay measurement accuracy. For example, a higher threshold value may overestimate the overlay error and a lower threshold value may underestimate the overlay error. Further, such a method may require that the image of the pattern be normalized as any variation in intensity across the image may result in an inaccurate determination of the position of the center for various features. While there may be other methods to determine the location of a center of the hole, these methods are not accurate. For example, an ellipse fitting method, which finds the edge points of a hole and fits the detected edge points to an ellipse, assumes that the hole is shaped like an ellipse, which may result in an inaccurate determination of the center if the actual shape of the hole is not an ellipse. Similarly, a template matching method, which locates a hole with a pre-defined template and designates the template center as the hole center, assumes the hole is shaped like a circle or the hole matches with a limited set of template shapes, which may result in an inaccurate determination of the center if the shape of the hole is not a circle. These and other drawbacks exist.

Disclosed are embodiments for automatically selecting a threshold value for processing an image representation (e.g., a gray-scale image) of a pattern to determine attributes of a feature of the pattern. For example, an image of the pattern is iteratively processed using threshold values in a specified search range and a two-dimensional (2D) profile of a feature (e.g., a hole representing a via) is generated for each threshold value and a characteristic parameter or key performance indicator (KPI) value is determined for each 2D profile. A threshold value corresponding to a KPI value that matches a target KPI value may be selected as an optimal threshold value for determining the attribute of the feature (e.g., a center of the hole). In some embodiments, a KPI is a function of attributes (e.g., geometrical attributes) of the 2D profile. In some embodiments, the optimal threshold value is where the actual 2D profile intersects with an ideal 2D profile, which can result in a symmetric 2D hole blob (e.g., height=width). By automatically determining the threshold value based on a KPI, the embodiments facilitate in determining a position of the feature without being limited to a specific user input of the threshold value, or to a particular shape of the 2D profile, thereby resulting in a more accurate determination of (a) the position of the feature, and (b) a defect (e.g., an overlay error). Further, since the embodiments may process each feature in the image independently, the process is tolerant to the image intensity variations across the image, which eliminates the need for normalizing the image, thereby minimizing the time and computing resources consumed in determining the defects. Thus, the embodiments provide an improved defect detection process.

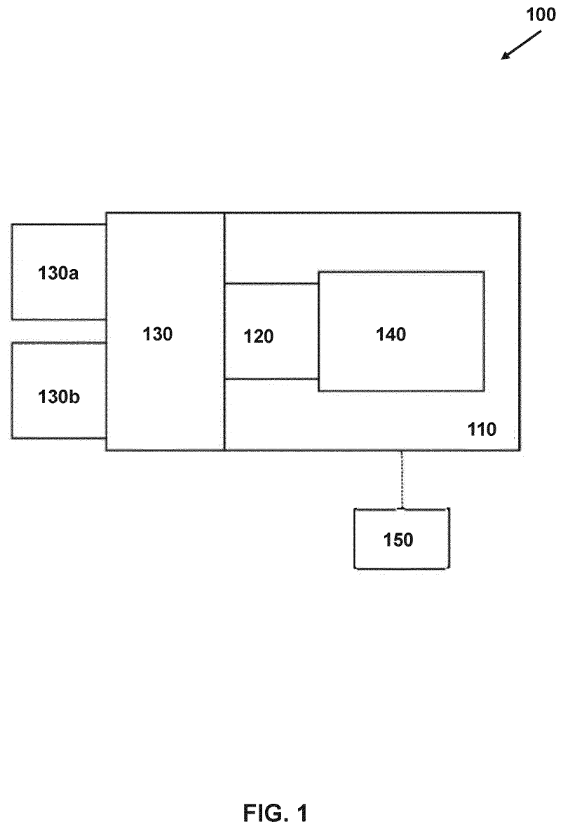

Reference is now made to FIG. 1, which illustrates an exemplary electron beam inspection (EBI) system 100 consistent with embodiments of the present disclosure. As shown in FIG. 1, EBI system 100 includes a main chamber 110, a load-lock chamber 120, an electron beam tool 140, and an equipment front end module (EFEM) 130. Electron beam tool 140 is located within main chamber 110. The exemplary EBI system 100 may be a single or multi-beam system. While the description and drawings are directed to an electron beam, it is appreciated that the embodiments are not used to limit the present disclosure to specific charged particles.

EFEM 130 includes a first loading port 130a and a second loading port 130b. EFEM 130 may include additional loading port(s). First loading port 130a and second loading port 130b receive wafer front opening unified pods (FOUPs) that contain wafers (e.g., semiconductor wafers or wafers made of other material(s)) or samples to be inspected (wafers and samples are collectively referred to as “wafers” hereafter). One or more robot arms (not shown) in EFEM 130 transport the wafers to load-lock chamber 120.

Load-lock chamber 120 is connected to a load/lock vacuum pump system (not shown), which removes gas molecules in load-lock chamber 120 to reach a first pressure below the atmospheric pressure. After reaching the first pressure, one or more robot arms (not shown) transport the wafer from load-lock chamber 120 to main chamber 110. Main chamber 110 is connected to a main chamber vacuum pump system (not shown), which removes gas molecules in main chamber 110 to reach a second pressure below the first pressure. After reaching the second pressure, the wafer is subject to inspection by electron beam tool 140. In some embodiments, electron beam tool 140 may comprise a single-beam inspection tool.

Controller 150 may be electronically connected to electron beam tool 140 and may be electronically connected to other components as well. Controller 150 may be a computer configured to execute various controls of EBI system 100. Controller 150 may also include processing circuitry configured to execute various signal and image processing functions. While controller 150 is shown in FIG. 1 as being outside of the structure that includes main chamber 110, load-lock chamber 120, and EFEM 130, it is appreciated that controller 150 can be part of the structure.

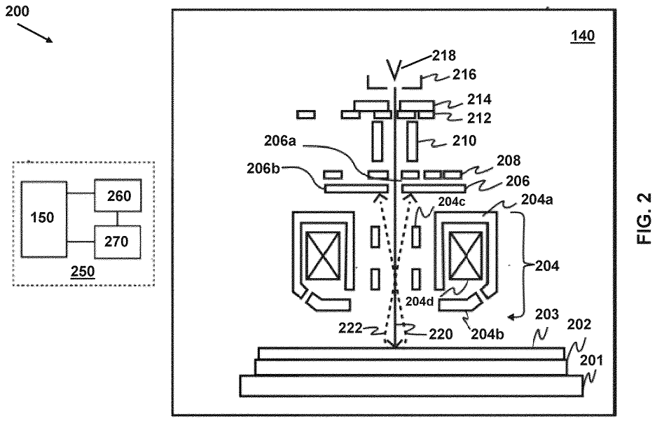

FIG. 2 illustrates schematic diagram of an exemplary imaging system 200 according to embodiments of the present disclosure. Electron beam tool 140 of FIG. 2 may be configured for use in EBI system 100. Electron beam tool 140 may be a single beam apparatus or a multi-beam apparatus. As shown in FIG. 2, electron beam tool 140 includes a motorized sample stage 201, and a wafer holder 202 supported by motorized sample stage 201 to hold a wafer 203 to be inspected. Electron beam tool 140 further includes an objective lens assembly 204, an electron detector 206 (which includes electron sensor surfaces 206a and 206b), an objective aperture 208, a condenser lens 210, a beam limit aperture 212, a gun aperture 214, an anode 216, and a cathode 218. Objective lens assembly 204, in some embodiments, may include a modified swing objective retarding immersion lens (SORIL), which includes a pole piece 204a, a control electrode 204b, a deflector 204c, and an exciting coil 204d. Electron beam tool 140 may additionally include an Energy Dispersive X-ray Spectrometer (EDS) detector (not shown) to characterize the materials on wafer 203.

A primary electron beam 220 is emitted from cathode 218 by applying a voltage between anode 216 and cathode 218. Primary electron beam 220 passes through gun aperture 214 and beam limit aperture 212, both of which may determine the size of electron beam entering condenser lens 210, which resides below beam limit aperture 212. Condenser lens 210 focuses primary electron beam 220 before the beam enters objective aperture 208 to set the size of the electron beam before entering objective lens assembly 204. Deflector 204c deflects primary electron beam 220 to facilitate beam scanning on the wafer. For example, in a scanning process, deflector 204c may be controlled to deflect primary electron beam 220 sequentially onto different locations of top surface of wafer 203 at different time points, to provide data for image reconstruction for different parts of wafer 203. Moreover, deflector 204c may also be controlled to deflect primary electron beam 220 onto different sides of wafer 203 at a particular location, at different time points, to provide data for stereo image reconstruction of the wafer structure at that location. Further, in some embodiments, anode 216 and cathode 218 may be configured to generate multiple primary electron beams 220, and electron beam tool 140 may include a plurality of deflectors 204c to project the multiple primary electron beams 220 to different parts/sides of the wafer at the same time, to provide data for image reconstruction for different parts of wafer 203.

Exciting coil 204d and pole piece 204a generate a magnetic field that begins at one end of pole piece 204a and terminates at the other end of pole piece 204a. A part of wafer 203 being scanned by primary electron beam 220 may be immersed in the magnetic field and may be electrically charged, which, in turn, creates an electric field. The electric field reduces the energy of impinging primary electron beam 220 near the surface of wafer 203 before it collides with wafer 203. Control electrode 204b, being electrically isolated from pole piece 204a, controls an electric field on wafer 203 to prevent micro-arching of wafer 203 and to ensure proper beam focus.

A secondary electron beam 222 may be emitted from the part of wafer 203 upon receiving primary electron beam 220. Secondary electron beam 222 may form a beam spot on sensor surfaces 206a and 206b of electron detector 206. Electron detector 206 may generate a signal (e.g., a voltage, a current, etc.) that represents an intensity of the beam spot, and provide the signal to an image processing system 250. The intensity of secondary electron beam 222, and the resultant beam spot, may vary according to the external or internal structure of wafer 203. Moreover, as discussed above, primary electron beam 220 may be projected onto different locations of the top surface of the wafer or different sides of the wafer at a particular location, to generate secondary electron beams 222 (and the resultant beam spot) of different intensities. Therefore, by mapping the intensities of the beam spots with the locations of wafer 203, the processing system may reconstruct an image that reflects the internal or surface structures of wafer 203.

Imaging system 200 may be used for inspecting a wafer 203 on sample stage 201, and comprises an electron beam tool 140, as discussed above. Imaging system 200 may also comprise an image processing system 250 that includes an image acquirer 260, storage 270, and controller 150. Image acquirer 260 may comprise one or more processors. For example, image acquirer 260 may comprise a computer, server, mainframe host, terminals, personal computer, any kind of mobile computing devices, and the like, or a combination thereof. Image acquirer 260 may connect with a detector 206 of electron beam tool 140 through a medium such as an electrical conductor, optical fiber cable, portable storage media, IR, Bluetooth, internet, wireless network, wireless radio, or a combination thereof. Image acquirer 260 may receive a signal from detector 206 and may construct an image. Image acquirer 260 may thus acquire images of wafer 203. Image acquirer 260 may also perform various post-processing functions, such as generating contours, superimposing indicators on an acquired image, and the like. Image acquirer 260 may be configured to perform adjustments of brightness and contrast, etc. of acquired images. Storage 270 may be a storage medium such as a hard disk, cloud storage, random access memory (RAM), other types of computer readable memory, and the like. Storage 270 may be coupled with image acquirer 260 and may be used for saving scanned raw image data as original images, and post-processed images. Image acquirer 260 and storage 270 may be connected to controller 150. In some embodiments, image acquirer 260, storage 270, and controller 150 may be integrated together as one control unit.

In some embodiments, image acquirer 260 may acquire one or more images of a sample based on an imaging signal received from detector 206. An imaging signal may correspond to a scanning operation for conducting charged particle imaging. An acquired image may be a single image comprising a plurality of imaging areas. The single image may be stored in storage 270. The single image may be an original image that may be divided into a plurality of regions. Each of the regions may comprise one imaging area containing a feature of wafer 203.

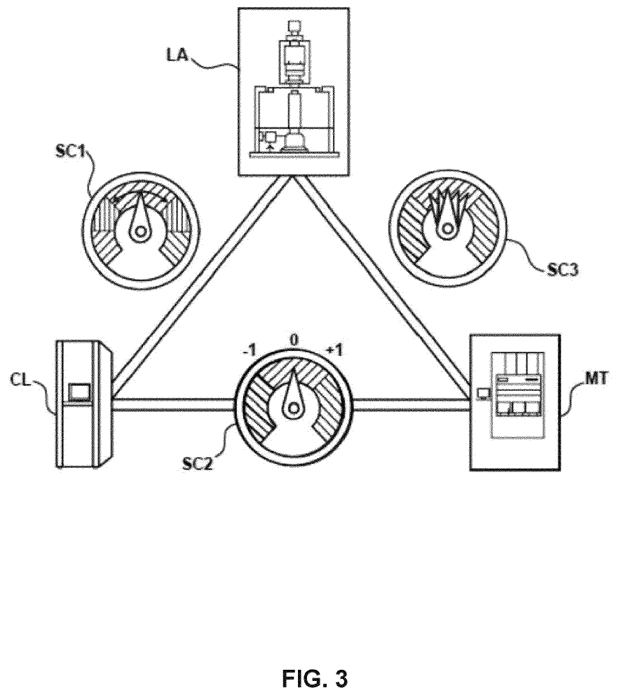

FIG. 3 depicts a schematic representation of holistic lithography, representing a cooperation between three technologies to optimize semiconductor manufacturing. Typically, the patterning process in a lithographic apparatus LA is one of the most critical steps in the processing which requires high accuracy of dimensioning and placement of structures on the substrate W (FIG. 1). To ensure this high accuracy, three systems (in this example) may be combined in a so called “holistic” control environment as schematically depicted in FIG. 3. One of these systems is the lithographic apparatus LA which is (virtually) connected to a metrology apparatus (e.g., a metrology tool) MT (a second system), and to a computer system CL (a third system). A “holistic” environment may be configured to optimize the cooperation between these three systems to enhance the overall process window and provide tight control loops to ensure that the patterning performed by the lithographic apparatus LA stays within a process window. The process window defines a range of process parameters (e.g., dose, focus, overlay) within which a specific manufacturing process yields a defined result (e.g., a functional semiconductor device)—typically within which the process parameters in the lithographic process or patterning process are allowed to vary.

The computer system CL may use (part of) the design layout to be patterned to predict which resolution enhancement techniques to use and to perform computational lithography simulations and calculations to determine which mask layout and lithographic apparatus settings achieve the largest overall process window of the patterning process (depicted in FIG. 2 by the double arrow in the first scale SC1). Typically, the resolution enhancement techniques are arranged to match the patterning possibilities of the lithographic apparatus LA. The computer system CL may also be used to detect where within the process window the lithographic apparatus LA is currently operating (e.g., using input from the metrology tool MT) to predict whether defects may be present due to, for example, sub-optimal processing (depicted in FIG. 2 by the arrow pointing “0” in the second scale SC2).

The metrology apparatus (tool) MT may provide input to the computer system CL to enable accurate simulations and predictions, and may provide feedback to the lithographic apparatus LA to identify possible drifts, e.g., in a calibration status of the lithographic apparatus LA (depicted in FIG. 3 by the multiple arrows in the third scale SC3).

The following paragraphs describe a system and a method for automatically selecting a threshold value for processing an image of a pattern to determine an attribute of a feature of the pattern. The following paragraphs describe the process for determining an attribute of a feature, such as a center of a hole (e.g., a via in the pattern) as an example of the attribute and the feature. However, it has to be noted that neither the feature is limited to a hole nor is the attribute of the feature limited to a center of the hole. The embodiments are applicable to other features or other attributes of a feature. In some embodiments, an image representation of a pattern may include a gray-scale image. The image may be measured, simulated, or otherwise generated using various methods and instruments. For example, the image be generated using a metrology tool, such as a single-beam SEM, multi-beam SEM, or an optical metrology tool, by capturing a pattern printed on a substrate. In another example, the image may be generated using a simulation model (e.g., a physical model, an empirical model, an artificial intelligence (AI) model, etc.) that generates the image based on pattern data, such as a target layout of the pattern to be printed on the substrate.

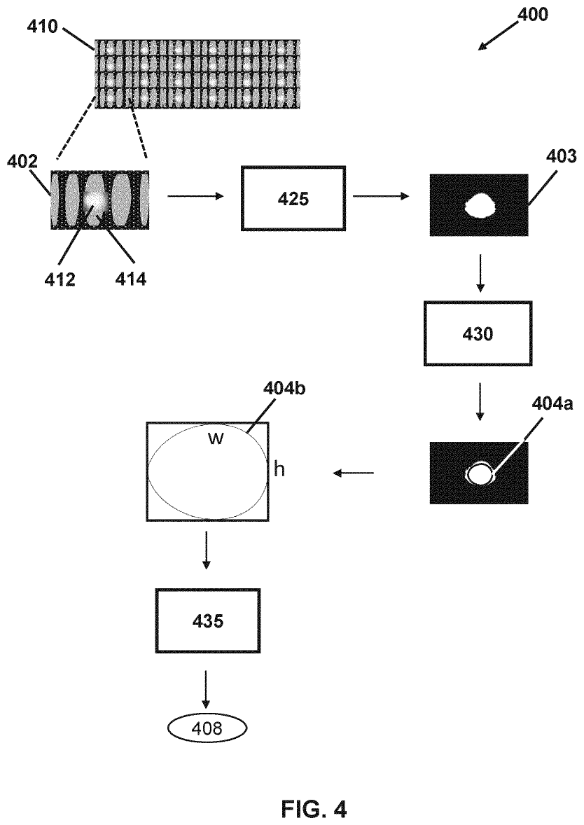

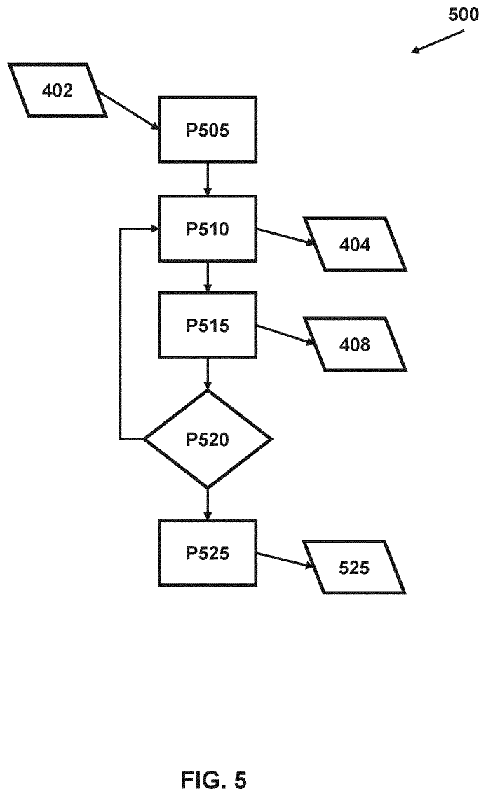

FIG. 4 is a block diagram of an exemplary system 400 for automatically selecting a threshold value for processing an image of a pattern to determine an attribute of a feature, consistent with various embodiments. FIG. 5 is a flow diagram of an exemplary method 500 for automatically selecting a threshold value for processing an image of a pattern to determine an attribute of a feature, consistent with various embodiments.

At process P505, an image processing component 425 obtains an image representation of a pattern. The image representation may be an image of the pattern having multiple features such as a hole 412 for which the center is to be determined. The image representation may be an image 410 that includes multiple holes, or an image 402 which includes a single hole 412. In some embodiments, if the image 410 having multiple holes is provided as input, the image processing component 425 may segment the image 410 into a number of smaller portions where each portion (e.g., image 402) contains a single hole. In some embodiments, the image 402 is an enlarged version of one of the holes in the image 410.

At process P510, a 2D profile generation component 430 generates a 2D profile 404a of the hole 412 using a first threshold value. In some embodiments, the image processing component 425 generates a thresholded image 403 by thresholding the image 402 using the first threshold value from a range of threshold values. The range of threshold values may be provided as a user input. The thresholded image 403 may be a binary image generated based on the pixel values of the image 402 and the first threshold value. For example, all those pixels with a value below the first threshold value may be assigned a “0” value (which corresponds to the white region in the thresholded image 403) and those equal to or above the first threshold value may be assigned a “1” value (which corresponds to the black region in the thresholded image 403). The white region in the thresholded image 403 corresponds to the hole 412. The 2D profile generation component 430 generates a 2D profile 404a from the thresholded image 403. FIG. 4 shows an enlarged version 404b of the 2D profile 404a. In some embodiments, the 2D profile 404a may represent a shape and size of the hole 412. The 2D profile 404 may be generated in any of a number of ways.

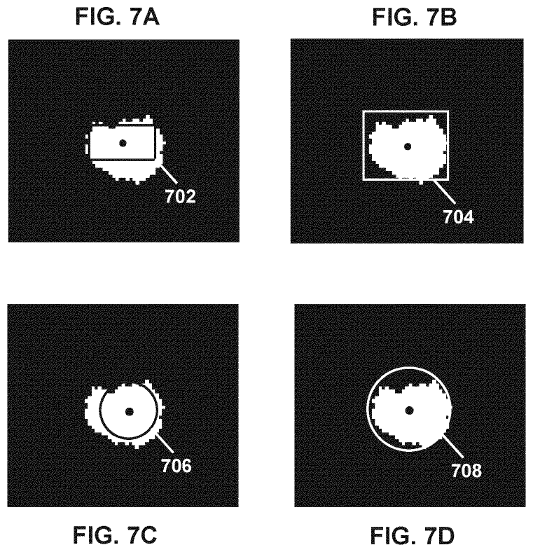

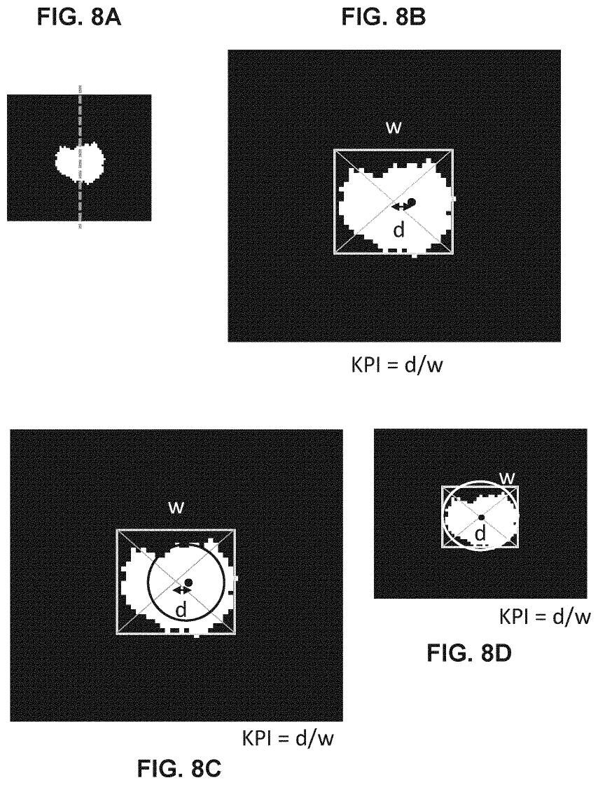

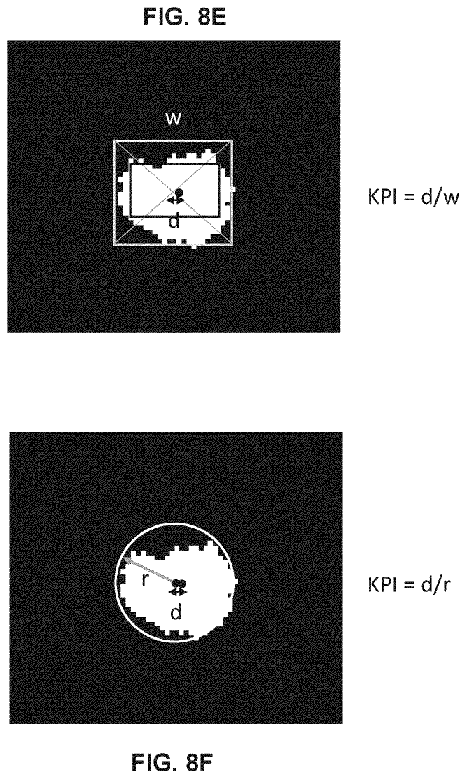

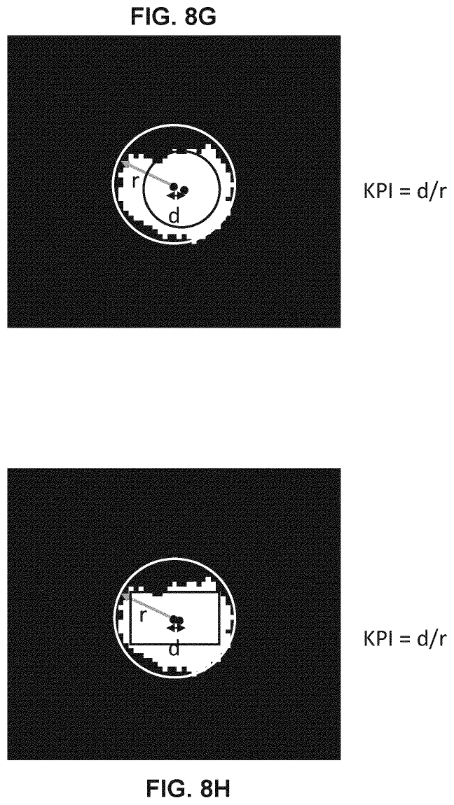

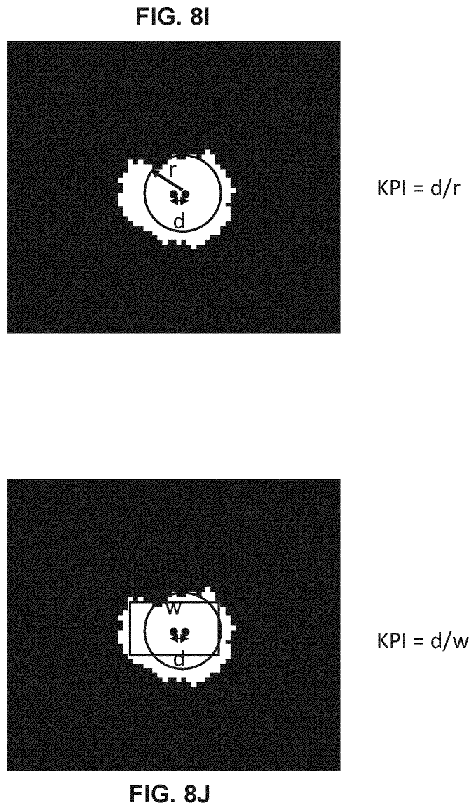

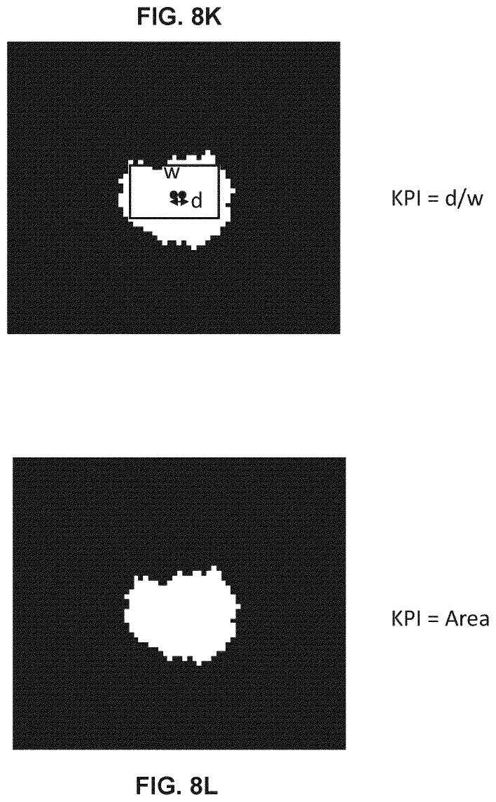

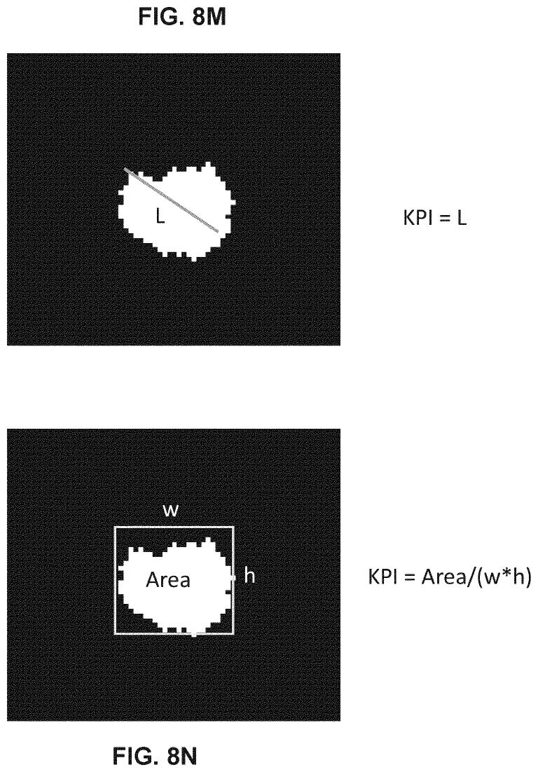

At process P515, a KPI evaluation component 435 evaluates the 2D profile 404 to determine a value of a KPI 408 of the 2D profile 404. The KPI 408 may be defined as a function of attributes associated with, or derived using, the 2D profile 404. In some embodiments, the KPI 408 may be defined as a function of geometrical attributes, e.g., a height (h) and width (w), of a bounding box of the 2D profile 404 of the hole 412. For example, the KPI 408 may be defined as an aspect ratio of the 2D profile—KPI=h/w. Various other KPIs may be defined to measure a performance of the 2D profile 404. Some examples of the KPIs are illustrated with reference to FIGS. 7A and 8A-8N below.

At determination process P520, the 2D profile generation component 430 determines whether a 2D profile has been generated for all threshold values of the specified range. Based on a determination that the 2D profile has not been generated for all the threshold values, the image processing component 425 proceeds with a next iteration in which a 2D profile is generated for a next threshold value from the specified range and the KPI value for the corresponding 2D profile is determined. As described above, the range of threshold values may be provided as a user input to the method 500. In some embodiments, a step size that indicates an amount by which the threshold value has to be increased for every iteration may also be provided as a user input to the method 500. For example, if the range of threshold values is indicated as “100”-“150” with a step size of “2,” then the method increases the threshold value by “2” for every iteration of generating the 2D profile starting from “100”, then to “102”, “104” and so on until “150”.

Referring back to the determination process P520, based on a determination that the 2D profiles are generated for all the threshold values in the range, at process P525, the KPI evaluation component 435 determines a KPI value among the KPI values that matches a target KPI value. In some embodiments, the target KPI value may be a value that is indicative of an ideal or nominal 2D profile of a feature that facilitates in an accurate determination of a position of the feature (e.g., center of the hole 412). The target KPI value may be established using any of various methods. For example, the target KPI value may be calculated using the 2D profiles of holes whose center coordinates and overlay errors with the other features are known. The target KPI value may be provided as a user input to the KPI evaluation component 435. The KPI 408 value matches the target KPI value if a specified criterion is satisfied. For example, the KPI 408 value may match the target value if the KPI 408 value is the same as the target KPI value. In another example, the KPI 408 may match the target value if the KPI 408 value exceeds the target KPI value. In another example, the KPI 408 value may match the target value if the difference between the KPI 408 value and the target KPI value is less than a threshold difference. In another example, the KPI 408 value may match the target value if the KPI 408 value is the closest among all the KPI values to the target KPI value.

After a matching KPI value is identified, the KPI evaluation component 435 determines a threshold value that corresponds to the matching KPI value as an optimal threshold value 525 that may be used to determine a center of the hole 412. In some embodiments, the optimal threshold value is where the actual 2D profile intersects with an ideal 2D profile, which can result in a symmetric 2D hole blob (e.g., height=width).

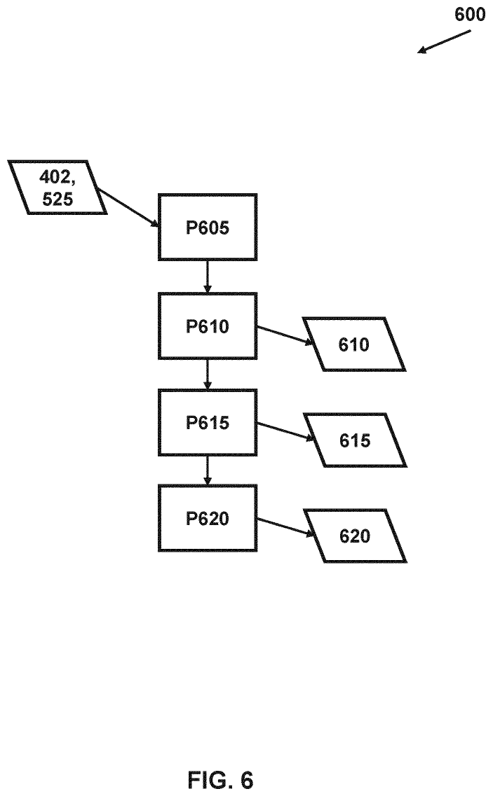

FIG. 6 is a flow diagram of an exemplary method 600 for determining an overlay error between features of a pattern using automatic thresholding, consistent with various embodiments. At process P605, an image of a pattern and a threshold value for generating a 2D profile of a feature in the pattern are obtained. In some embodiments, the image may be an image of a pattern having multiple features. For example, the image be an image 402 which has multiple features such as a hole 412 and a second feature 414. The threshold value may be a specified threshold value that is automatically selected based on a KPI of a 2D profile of the feature for which a position (e.g., a center of the hole 412) is to be determined. For example, the specified threshold value may be the threshold value 525 that is selected using the method 500 described above at least with reference to FIG. 5.

At process P610, the 2D profile generation component 430 generates a 2D profile 610 of the hole 412 (e.g., as described at least with reference to FIG. 5 above). In some embodiments, the 2D profile 610 may be similar to the 2D profile 404 of FIG. 4.

At process P615, the 2D profile generation component 430 determines a location of a center 615 of the hole 412 based on the 2D profile 610. In some embodiments, the center 615 may include any of a centroid, a center of geometry, or a center of gravity of the 2D profile 610. Any of a number of methods may be used to determine the center 615 using the 2D profile 610.

At process P620, the 2D profile generation component 430 determines an overlay error 620 between the hole 412 and another feature of the pattern such as the second feature 414. For example, the 2D profile generation component 430 obtains the location of the second feature 414 and determines the overlay error 620 with the hole 412 using the location of the second feature 414 and the location of the center 615 of the hole 412 (e.g., determined in process P615).

In some embodiments, the method 500 of FIG. 5 may performed for each hole in the pattern independently to determine an optimal threshold value for each hole. For example, if the image representation input to the method 500 is the image 410, which includes multiple holes, then the method 500 is performed for each of the holes in the image 410 to select an optimal threshold value for the corresponding hole. Similarly, the method 600 is repeated for each of the holes for determining the center of a corresponding hole and the overlay error between the corresponding hole and another feature. One of the advantages of determining the threshold value for each hole independently is that the method is tolerant to any variations (e.g., image intensity) across the image, which eliminates the need for normalizing an image, which minimizes the consumption of time and computing resources, thereby making the defect detection faster.

The KPI of a 2D profile of a feature may be defined using various geometrical attributes associated with the 2D profile. FIGS. 7A-7D illustrate various geometrical attributes that may be used in defining a KPI of a 2D profile of a feature, consistent with various embodiments. As illustrated in FIG. 7A, a maximum inclosing rectangle 702 is determined for a 2D blob associated with a feature, and a center of the maximum inclosing rectangle 702 may be used in the formulation of a KPI of the 2D profile. In some embodiments, a maximum inclosing rectangle is the largest rectangle that can be contained in the 2D blob.

In another example, as illustrated in FIG. 7B, a minimum bounding box or a minimum enclosing rectangle 704 is determined for the 2D blob and a center of the minimum enclosing rectangle 704 may be used in the formulation of a KPI of the 2D profile. In some embodiments, the minimum enclosing rectangle is the smallest rectangle that can contain the 2D blob.

In another example, as illustrated in FIG. 7C, a maximum inclosing circle 706 is determined for the 2D blob and a center of the maximum inclosing circle 706 may be used in the formulation of a KPI of the 2D profile. In some embodiments, a maximum inclosing circle is the largest circle that can be contained in the 2D blob.

In another example, as illustrated in FIG. 7D, a minimum bounding or enclosing circle 708 is determined for the 2D profile of a feature and a center of the minimum enclosing circle 708 may be used in the formulation of a KPI of the 2D profile. In some embodiments, the minimum enclosing circle is the smallest circle that can contain the 2D blob.

One or more centers of the geometrical shapes described in the above figures may be used in defining various KPIs, as illustrated in FIGS. 8A-8N below.

FIGS. 8A-8N illustrate various KPIs associated with a 2D profile, consistent with various embodiments. In a first example, as illustrated in FIG. 8A, a KPI of a 2D profile may be defined based on a reflection symmetry of the 2D profile. A vertical axis that passes through the 2D profile center (e.g., a centroid, center of geometry, or center of gravity of the 2D profile) is determined. A first KPI is determined based on attributes of the 2D profile image before flipping the image and after flipping the image across the vertical axis. For example, the first KPI is determined as a sum of pixel arithmetic difference between an original image and the flipped image. In some embodiments, this symmetry may describe the divergence from an ideal left-right symmetric shape.

FIG. 8B shows a minimum enclosing rectangle that encloses a 2D profile of the hole. A second KPI may be defined based on a width, w, of the minimum enclosing rectangle, and a distance or a horizontal difference, d, between the center of the minimum enclosing rectangle and a 2D profile center. For example, the second KPI may be represented as KPI=d/w. In some embodiments, the distance, d, describes the divergence from a symmetric blob.

FIG. 8C shows a minimum enclosing rectangle and maximum inclosing circle associated with a 2D profile of the hole. A third KPI may be defined based on a width, w, of the minimum enclosing rectangle, and a distance or a horizontal difference, d, between the center of the minimum enclosing rectangle and a center of the maximum enclosing circle. For example, the third KPI may be represented as KPI=d/w. In some embodiments, the distance, d, describes the divergence from a symmetric blob. In some embodiments, the third KPI is more sensitive to a change in concave shape of the 2D profile.

FIG. 8D shows a minimum enclosing rectangle and a minimum enclosing circle associated with a 2D profile of the hole. A fourth KPI may be defined based on a width, w, of the minimum enclosing rectangle, and a distance or a horizontal difference, d, between the centers of the minimum enclosing rectangle and the circle. For example, the fourth KPI may be represented as KPI=d/w. In some embodiments, the distance, d, describes the divergence from a symmetric blob. In some embodiments, the fourth KPI is more sensitive to a change in concave shape of the 2D profile.

FIG. 8E shows a minimum enclosing rectangle and a maximum inclosing rectangle associated with a 2D profile of the hole. A fifth KPI may be defined based on a width, w, of the minimum enclosing rectangle, and a distance or a horizontal difference, d, between the centers of the minimum enclosing and maximum inclosing rectangles. For example, the fifth KPI may be represented as KPI=d/w. In some embodiments, the distance, d, describes the divergence from a symmetric blob. In some embodiments, the fifth KPI is sensitive to horizontal cropping and not sensitive to vertical cropping as the threshold changes.

FIG. 8F shows a minimum enclosing circle associated with a 2D profile of the hole. A sixth KPI may be defined based on a radius, r, of the minimum enclosing circle, and a distance or a horizontal difference, d, between the center of the minimum enclosing circle and the 2D profile center. For example, the sixth KPI may be represented as KPI=d/r. In some embodiments, the distance, d, describes the divergence from a symmetric blob. In some embodiments, the sixth KPI is sensitive to the convex shape change when the threshold changes.

FIG. 8G shows a minimum enclosing circle and a maximum inclosing circle associated with a 2D profile of the hole. A seventh KPI may be defined based on a radius, r, of the minimum enclosing circle, and a distance or a horizontal difference, d, between the centers of the minimum enclosing and maximum inclosing circles. For example, the seventh KPI may be represented as KPI=d/r. In some embodiments, the distance, d, describes the divergence from a symmetric blob. In some embodiments, the seventh KPI is sensitive to both convex and concave shape change when the threshold changes.

FIG. 8H shows a minimum enclosing circle and a maximum inclosing rectangle associated with a 2D profile of the hole. An eighth KPI may be defined based on a radius, r, of the minimum enclosing circle, and a distance or a horizontal difference, d, between the centers of the minimum enclosing circle and the maximum inclosing rectangle. For example, the eighth KPI may be represented as KPI=d/r. In some embodiments, the distance, d, describes the divergence from a symmetric blob. In some embodiments, the eighth KPI is sensitive to convex shape change while insensitive to vertical cropping when the threshold changes.

FIG. 8I shows a maximum inclosing circle associated with a 2D profile of the hole. A ninth KPI may be defined based on a radius, r, of the maximum inclosing circle, and a distance or a horizontal difference, d, between the center of the maximum inclosing circle and a 2D profile center. For example, the ninth KPI may be represented as KPI=d/r. In some embodiments, the distance, d, describes the divergence from a symmetric blob. In some embodiments, the ninth KPI is sensitive to concave shape change when the threshold changes.

FIG. 8J shows a maximum inclosing circle and a maximum inclosing rectangle associated with a 2D profile of the hole. A tenth KPI may be defined based on a width, w, of the maximum enclosing rectangle, and a distance or a horizontal difference, d, between the centers of the maximum enclosing circle and rectangle. For example, the tenth KPI may be represented as KPI=d/w. In some embodiments, the distance, d, describes the divergence from a symmetric blob. In some embodiments, the tenth KPI is more sensitive to concave shape change along the horizontal direction when the threshold changes.

FIG. 8K shows a maximum inclosing rectangle associated with a 2D profile of the hole. An eleventh KPI may be defined based on a width, w, of the maximum inclosing rectangle, and a distance or a horizontal difference, d, between the center of the maximum inclosing rectangle and a 2D profile center. For example, the eleventh KPI may be represented as KPI=d/w. In some embodiments, the distance, d, describes the divergence from a symmetric blob. In some embodiments, the eleventh KPI is more sensitive to the horizontal cropping when the threshold changes.

FIG. 8L shows a 2D blob of the hole. A twelfth KPI may be determined based on an area of the 2D blob.

FIG. 8M shows a 2D blob of the hole. A thirteenth KPI may be determined based on a diameter, L, of the 2D blob. For example, the thirteenth KPI may be defined based on maximum Feret diameter of the 2D blob. In some embodiments, the maximum Feret diameter may be a longest distance between two points of the 2D blob. The thirteenth KPI describes the hole's widest extension along one direction.

FIG. 8N shows a minimum enclosing rectangle associated with a 2D profile of the hole. A fourteenth KPI may be defined based on an area of the 2D blob and the dimensions such as a height, h, and width, w, of the minimum enclosing rectangle. For example, the fourteenth KPI may be represented as KPI=Area/(w*h). In some embodiments, the fourteenth KPI describes if the hole pixels are extended or consolidated.

Another KPI may be defined based on ellipse fitting. For example, the edge of the 2D blob may be fitted with an ellipse (e.g., using the least square method) and an eccentricity of the fitted ellipse may be used as the KPI. In some embodiments, eccentricity describes the divergence of the 2D profile shape from a circular shape. If the length of the ellipse major axis is represented as “2a” and that of minor axis is represented as “2b,” then eccentricity, e, may be represented as follows:

$$e = \sqrt{1 - \frac{{b}^{2}}{{a}^{2}}}$$

In some embodiments, a KPI may be generated from one or more KPIs. For example, a first composite KPI, which is a combination of the aspect ratio KPI (e.g., described at least with reference to FIGS. 4 and 5) and the second KPI of FIG. 8B, may be defined as follows:

$$KPI = \sqrt{{( \frac{h}{w} - 1. )}^{2} + {( \frac{d}{w} )}^{2}}$$

The above KPI may optimize the aspect ratio towards 1.0 and try to keep the 2D profile as symmetric as possible.

In another example, a second composite KPI, which is a combination of the aspect ratio KPI (e.g., described at least with reference to FIGS. 4 and 5) and the third KPI of FIG. 8C, may be defined as follows:

$$KPI = \sqrt{{( \frac{h}{w} - 0.95 )}^{2} + {( \frac{d}{w} - 0.1 )}^{2}}$$

The above KPI tries to optimize the 2D profile to an egg shape.

Note that any of the above KPIs and/or other KPIs may be used (e.g., in method 500) for selecting a threshold value to determine a center of the hole. Further, a target value for any of these KPIs may be provided as a user input.

In some embodiments, the defect detection process helps in improving a patterning process by minimizing defects in patterning a target layout on a substrate. For example, based on the determined overlay error, a parameter of a patterning process or a lithographic apparatus used to print a pattern on a substrate may be adjusted to minimize defects in patterning a target layout on the substrate. After adjusting the parameter, the patterning process may be performed using the lithographic apparatus to print patterns corresponding to the target layout on the substrate.

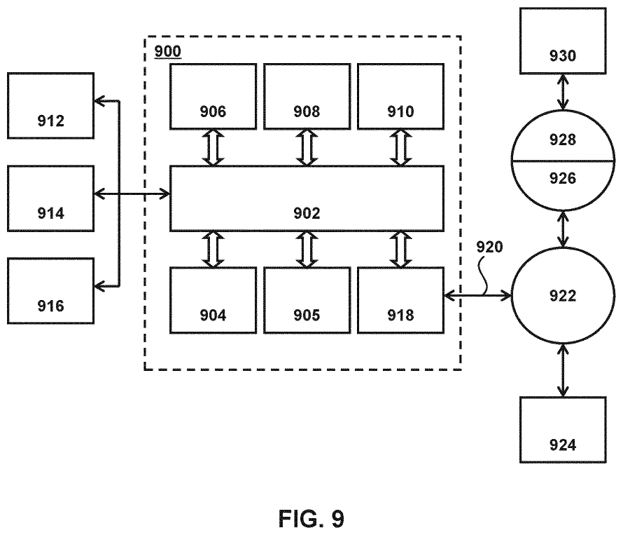

FIG. 9 is a block diagram that illustrates a computer system 900 which can assist in implementing in various methods and systems disclosed herein. The computer system 900 may be used to implement any of the entities, components, modules, or services depicted in the examples of the figures (and any other entities, components, modules, or services described in this specification). The computer system 900 may be programmed to execute computer program instructions to perform functions, methods, flows, or services (e.g., of any of the entities, components, or modules) described herein. The computer system 900 may be programmed to execute computer program instructions by at least one of software, hardware, or firmware.

Computer system 900 includes a bus 902 or other communication mechanism for communicating information, and a processor 904 (or multiple processors 904 and 905) coupled with bus 902 for processing information. Computer system 900 also includes a main memory 906, such as a random access memory (RAM) or other dynamic storage device, coupled to bus 902 for storing information and instructions to be executed by processor 904. Main memory 906 also may be used for storing temporary variables or other intermediate information during execution of instructions to be executed by processor 904. Computer system 900 further includes a read only memory (ROM) 908 or other static storage device coupled to bus 902 for storing static information and instructions for processor 904. A storage device 910, such as a magnetic disk or optical disk, is provided and coupled to bus 902 for storing information and instructions.

Computer system 900 may be coupled via bus 902 to a display 912, such as a cathode ray tube (CRT) or flat panel or touch panel display for displaying information to a computer user. An input device 914, including alphanumeric and other keys, is coupled to bus 902 for communicating information and command selections to processor 904. Another type of user input device is cursor control 916, such as a mouse, a trackball, or cursor direction keys for communicating direction information and command selections to processor 904 and for controlling cursor movement on display 912. This input device typically has two degrees of freedom in two axes, a first axis (e.g., x) and a second axis (e.g., y), that allows the device to specify positions in a plane. A touch panel (screen) display may also be used as an input device.

According to one embodiment, portions of one or more methods described herein may be performed by computer system 900 in response to processor 904 executing one or more sequences of one or more instructions contained in main memory 906. Such instructions may be read into main memory 906 from another computer-readable medium, such as storage device 910. Execution of the sequences of instructions contained in main memory 906 causes processor 904 to perform the process steps described herein. One or more processors in a multi-processing arrangement may also be employed to execute the sequences of instructions contained in main memory 906. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor 904 for execution. Such a medium may take many forms, including but not limited to, non-volatile media, volatile media, and transmission media. Non-volatile media include, for example, optical or magnetic disks, such as storage device 910. Volatile media include dynamic memory, such as main memory 906. Transmission media include coaxial cables, copper wire and fiber optics, including the wires that comprise bus 902. Transmission media can also take the form of acoustic or light waves, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge, a carrier wave as described hereinafter, or any other medium from which a computer can read.

Various forms of computer readable media may be involved in carrying one or more sequences of one or more instructions to processor 904 for execution. For example, the instructions may initially be borne on a magnetic disk of a remote computer. The remote computer can load the instructions into its dynamic memory and send the instructions over a telephone line using a modem. A modem local to computer system 900 can receive the data on the telephone line and use an infrared transmitter to convert the data to an infrared signal. An infrared detector coupled to bus 902 can receive the data carried in the infrared signal and place the data on bus 902. Bus 902 carries the data to main memory 906, from which processor 904 retrieves and executes the instructions. The instructions received by main memory 906 may optionally be stored on storage device 910 either before or after execution by processor 904.

Computer system 900 also preferably includes a communication interface 918 coupled to bus 902. Communication interface 918 provides a two-way data communication coupling to a network link 920 that is connected to a local network 922. For example, communication interface 918 may be an integrated services digital network (ISDN) card or a modem to provide a data communication connection to a corresponding type of telephone line. As another example, communication interface 918 may be a local area network (LAN) card to provide a data communication connection to a compatible LAN. Wireless links may also be implemented. In any such implementation, communication interface 918 sends and receives electrical, electromagnetic, or optical signals that carry digital data streams representing various types of information.

Network link 920 typically provides data communication through one or more networks to other data devices. For example, network link 920 may provide a connection through local network 922 to a host computer 924 or to data equipment operated by an Internet Service Provider (ISP) 926. ISP 926 in turn provides data communication services through the worldwide packet data communication network, now commonly referred to as the “Internet” 928. Local network 922 and Internet 928 both use electrical, electromagnetic, or optical signals that carry digital data streams. The signals through the various networks and the signals on network link 920 and through communication interface 918, which carry the digital data to and from computer system 900, are exemplary forms of carrier waves transporting the information.

Computer system 900 can send messages and receive data, including program code, through the network(s), network link 920, and communication interface 918. In the Internet example, a server 930 might transmit a requested code for an application program through Internet 928, ISP 926, local network 922 and communication interface 918. One such downloaded application may provide for the illumination optimization of the embodiment, for example. The received code may be executed by processor 904 as it is received, or stored in storage device 910, or other non-volatile storage for later execution. In this manner, computer system 900 may obtain application code in the form of a carrier wave.

Embodiments of the present disclosure can be further described by the following clauses.
1. A method for selecting a threshold value in processing an image to determine characteristics of pattern to be printed on a substrate, the method comprising:
   accessing an image representation of a pattern;
   generating multiple profiles of a first feature of the pattern by processing the image representation using different threshold values, wherein each profile of the profiles corresponds to a respective threshold value;
   evaluating the profiles; and
   selecting a specified threshold value of the threshold values based on the evaluating.
2. The method of clause 1, wherein the evaluating includes:
   determining values of a characteristic parameter of the profiles.
3. The method of clause 2, wherein selecting the specified threshold value is based on a target value of the characteristic parameter.
4. The method of clause 2, wherein the characteristic parameter indicates an aspect ratio of the corresponding profile.
5. The method of clause 2, wherein the characteristic parameter is determined based on one or more attributes associated with, or derived using, a profile of the first feature.
6. The method of clause 1, wherein generating the profiles includes:
   obtaining a range of the threshold values; and
   generating the profiles by iteratively selecting a threshold value in the range of the threshold values.
7. The method of clause 6, wherein generating the profiles by iteratively selecting the threshold value includes:
   obtaining a step size of the threshold values for the iterating.
8. The method of clause 1, wherein the image representation is a gray-scale image.
9. The method of clause 1, wherein the image representation is an image of the pattern captured using a metrology tool.
10. The method of clause 9, wherein the metrology tool includes a scanning electron microscope.
11. The method of clause 1, wherein the image representation is a simulated image generated using one or more simulation methods based on data of a second pattern to be printed on the substrate.
12. The method of clause 1, wherein the image representation represents a gray-scale image, and wherein generating the 2D profiles comprises:
generating a binary image based on pixel values of the gray-scale image and a first threshold value of the threshold values; and
generating a first profile of the profiles using the binary image.
13. The method of clause 1 further comprising:
   determining a center of the first feature from a profile of the profiles generated using the specified threshold value.
14. The method of clause 13, wherein the center of the first feature includes at least one of a center of gravity, a center of geometry, or a centroid of the first feature.
15. The method of clause 13 further comprising:
   determining an overlay between the first feature with another feature using the center of the first feature.
16. The method of clause 15 further comprising:
   adjusting a parameter of at least one of a patterning process or a lithographic apparatus based on the overlay to minimize defects in patterning a target layout on the substrate.
17. The method of clause 16 further comprising:
   performing the patterning process via the lithographic apparatus to print patterns corresponding to the target layout on the substrate.
18. The method of clause 1, wherein the first feature is a via structure in the pattern.
19. The method of clause 18 further comprising:
   for each of multiple via structures in the pattern,
      generating a set of profiles of the corresponding via structure for a set of threshold values;
      determining a set of values of a characteristic parameter of the set of profiles; and
      selecting a threshold value of the set of threshold values based on the set of values of the characteristic parameter and a target value of the characteristic parameter.
20. The method of clause 18 further comprising:
   determining an overlay of each of the via structures with another feature of the pattern using a center of the corresponding via structure.
21. The method of clause 20, wherein determining the overlay of each of the via structures includes:
   for each of multiple via structures in the pattern, determining a center of the corresponding via structure from a profile generated using a selected threshold value.
22. The method of clause 1, wherein each profile of the profiles is a two-dimensional (2D) profile.
23. A method for determining a center of a feature of a pattern by selecting a threshold value for processing an image representative of the pattern, the method comprising:
   accessing an image representation representative of a pattern;
   iteratively thresholding the image representation using different threshold values to generate multiple profiles of a first feature of the pattern, wherein each profile of the profiles corresponds to a respective threshold value;
   selecting a specified threshold value of the threshold values based on a characteristic parameter associated with the profiles; and
   determining a center of the first feature using a profile generated using the specified threshold value.
24. The method of clause 23 further comprising:
   determining an overlay between the first feature and another feature using the center of the first feature.
25. The method of clause 23, wherein the characteristic parameter indicates an aspect ratio of the corresponding profile.
26. The method of clause 23, wherein the characteristic parameter is determined based on one or more attributes associated with, or derived using, a profile of the first feature.
27. The method of clause 23, wherein iteratively thresholding the image representation includes:
   determining values of the characteristic parameter.
28. The method of clause 23, wherein selecting the specified threshold value is based on a target value of the characteristic parameter.
29. The method of clause 23, wherein iteratively thresholding the image representation includes:
   obtaining a range of the threshold values; and
   generating the profiles by iteratively selecting a threshold value in the range of the threshold values.
30. The method of clause 29, wherein generating the profiles by iteratively selecting the threshold value includes:
   obtaining a step size of the threshold values for the iterating.
31. The method of clause 23, wherein the image representation is a gray-scale image.
32. The method of clause 23, wherein the image representation is an image of the pattern captured using a metrology tool.
33. The method of clause 32, wherein the metrology tool includes a scanning electron microscope.
34. The method of clause 23, wherein the image representation is a simulated image generated using one or more simulation methods based on data of a second pattern to be printed on a substrate.
35. The method of clause 23, wherein the image representation represents a gray-scale image, and wherein the profiles are generated by:
   generating a binary image based on pixel values of the gray-scale image and a first threshold value of the threshold values; and
   generating a first profile of the profiles using the binary image.
36. The method of clause 23, wherein the center of the first feature includes at least one of a center of gravity, a center of geometry, or a centroid of the first feature.
37. The method of clause 23, wherein the first feature is a via structure in the pattern.
38. The method of clause 23, wherein each profile of the profiles is a 2D profile.
39. A non-transitory computer-readable medium having instructions recorded thereon, the instructions when executed by a computer implementing the method of any of the above clauses.
40. An apparatus comprising:
   a memory storing a set of instructions; and
   a processor configured to execute the set of instructions to cause the apparatus to perform a method of any of the above clauses.

While the concepts disclosed herein may be used for imaging on a substrate such as a silicon wafer, it shall be understood that the disclosed concepts may be used with any type of lithographic imaging systems, e.g., those used for imaging on substrates other than silicon wafers.

The terms “optimizing” and “optimization” as used herein refers to or means adjusting a patterning apparatus (e.g., a lithography apparatus), a patterning process, etc. such that results and/or processes have more desirable characteristics, such as higher accuracy of projection of a design pattern on a substrate, a larger process window, etc. Thus, the term “optimizing” and “optimization” as used herein refers to or means a process that identifies one or more values for one or more parameters that provide an improvement, e.g., a local optimum, in at least one relevant metric, compared to an initial set of one or more values for those one or more parameters. “Optimum” and other related terms should be construed accordingly. In an embodiment, optimization steps can be applied iteratively to provide further improvements in one or more metrics.

Aspects of the invention can be implemented in any convenient form. For example, an embodiment may be implemented by one or more appropriate computer programs which may be carried on an appropriate carrier medium which may be a tangible carrier medium (e.g., a disk) or an intangible carrier medium (e.g., a communications signal). Embodiments of the invention may be implemented using suitable apparatus which may specifically take the form of a programmable computer running a computer program arranged to implement a method as described herein. Thus, embodiments of the disclosure may be implemented in hardware, firmware, software, or any combination thereof. Embodiments of the disclosure may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical, or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc.

In block diagrams, illustrated components are depicted as discrete functional blocks, but embodiments are not limited to systems in which the functionality described herein is organized as illustrated. The functionality provided by each of the components may be provided by software or hardware modules that are differently organized than is presently depicted, for example such software or hardware may be intermingled, conjoined, replicated, broken up, distributed (e.g., within a data center or geographically), or otherwise differently organized. The functionality described herein may be provided by one or more processors of one or more computers executing code stored on a tangible, non-transitory, machine-readable medium. In some cases, third party content delivery networks may host some or all of the information conveyed over networks, in which case, to the extent information (e.g., content) is said to be supplied or otherwise provided, the information may be provided by sending instructions to retrieve that information from a content delivery network.

Unless specifically stated otherwise, as apparent from the discussion, it is appreciated that throughout this specification discussions utilizing terms such as “processing,” “computing,” “calculating,” “determining” or the like refer to actions or processes of a specific apparatus, such as a special purpose computer or a similar special purpose electronic processing/computing device.

The reader should appreciate that the present application describes several inventions. Rather than separating those inventions into multiple isolated patent applications, these inventions have been grouped into a single document because their related subject matter lends itself to economies in the application process. But the distinct advantages and aspects of such inventions should not be conflated. In some cases, embodiments address all of the deficiencies noted herein, but it should be understood that the inventions are independently useful, and some embodiments address only a subset of such problems or offer other, unmentioned benefits that will be apparent to those of skill in the art reviewing the present disclosure. Due to costs constraints, some inventions disclosed herein may not be presently claimed and may be claimed in later filings, such as continuation applications or by amending the present claims. Similarly, due to space constraints, neither the Abstract nor the Summary sections of the present document should be taken as containing a comprehensive listing of all such inventions or all aspects of such inventions.

It should be understood that the description and the drawings are not intended to limit the present disclosure to the particular form disclosed, but to the contrary, the intention is to cover all modifications, equivalents, and alternatives falling within the spirit and scope of the inventions as defined by the appended claims.

Modifications and alternative embodiments of various aspects of the inventions will be apparent to those skilled in the art in view of this description. Accordingly, this description and the drawings are to be construed as illustrative only and are for the purpose of teaching those skilled in the art the general manner of carrying out the inventions. It is to be understood that the forms of the inventions shown and described herein are to be taken as examples of embodiments. Elements and materials may be substituted for those illustrated and described herein, parts and processes may be reversed or omitted, certain features may be utilized independently, and embodiments or features of embodiments may be combined, all as would be apparent to one skilled in the art after having the benefit of this description. Changes may be made in the elements described herein without departing from the spirit and scope of the invention as described in the following claims. Headings used herein are for organizational purposes only and are not meant to be used to limit the scope of the description.

As used herein, unless specifically stated otherwise, the term “or” encompasses all possible combinations, except where infeasible. For example, if it is stated that a component includes A or B, then, unless specifically stated otherwise or infeasible, the component may include A, or B, or A and B. As a second example, if it is stated that a component includes A, B, or C, then, unless specifically stated otherwise or infeasible, the component may include A, or B, or C, or A and B, or A and C, or B and C, or A and B and C. Expressions such as “at least one of” do not necessarily modify an entirety of a following list and do not necessarily modify each member of the list, such that “at least one of A, B, and C” should be understood as including only one of A, only one of B, only one of C, or any combination of A, B, and C. The phrase “one of A and B” or “any one of A and B” shall be interpreted in the broadest sense to include one of A, or one of B.

The descriptions herein are intended to be illustrative, not limiting. Thus, it will be apparent to one skilled in the art that modifications may be made as described without departing from the scope of the claims set out below.

1. A method for determining a central location of a feature of a pattern by selecting a threshold value for processing an image representative of the pattern, the method comprising:
accessing an image representation representative of a pattern;
iteratively thresholding the image representation using different threshold values to generate multiple profiles of a first feature of the pattern, wherein each profile of the multiple profiles corresponds to a respective threshold value;
selecting a specified threshold value of the different threshold values based on a characteristic parameter associated with the multiple profiles; and
determining a central location of the feature using a profile generated using the specified threshold value.

2. The method of claim 1, further comprising determining an overlay between the first feature and another feature using the central location of the feature.

3. The method of claim 1, wherein the characteristic parameter indicates an aspect ratio of a corresponding profile.

4. The method of claim 1, wherein the characteristic parameter is determined based on one or more attributes associated with, or derived using, a profile of the first feature.

5. The method of claim 1, wherein iteratively thresholding the image representation includes determining values of the characteristic parameter.

6. The method of claim 1, wherein selecting the specified threshold value is based on a target value of the characteristic parameter.

7. The method of claim 1, wherein iteratively thresholding the image representation includes:
obtaining a range of the threshold values; and
generating the profiles by iteratively selecting a threshold value in the range of the threshold values,
wherein generating the profiles by iteratively selecting the threshold value includes obtaining a step size of the threshold values for the iterating.

8. The method of claim 1, wherein the image representation is an image of the pattern captured using a metrology tool.

9. The method of claim 8, wherein the metrology tool comprises a scanning electron microscope.

10. The method of claim 1, wherein the image representation is a simulated image generated using one or more simulation methods based on data of a further pattern to be printed on a substrate.

11. The method of claim 1, wherein the image representation represents a gray-scale image, and wherein the profiles are generated by:
generating a binary image based on pixel values of the gray-scale image and a first threshold value of the threshold values; and
generating a first profile of the profiles using the binary image.

12. The method of claim 1, wherein the central location of the feature includes at least one selected from: a center of gravity, a center of geometry, or a centroid of the first feature.

13. The method of claim 1, wherein the feature is a via structure in the pattern.

14. The method of claim 1, wherein each profile of the profiles is a 2D profile.

15. A non-transitory computer-readable medium having instructions recorded thereon, the instructions, when executed by a computer system, configured to cause the computer system to at least:
access an image representation representative of a pattern;
iteratively threshold the image representation using different threshold values to generate multiple profiles of a feature of the pattern, wherein each profile of the multiple profiles corresponds to a respective threshold value;
select a specified threshold value of the different threshold values based on a characteristic parameter associated with the multiple profiles; and
determine a central location of the feature using a profile generated using the specified threshold value.

16. A method for selecting a threshold value in processing an image to determine characteristics of a pattern to be printed on a substrate, the method comprising:
accessing an image representation of a pattern to be printed on a substrate;
generating multiple profiles of a feature of the pattern by processing the image representation using different threshold values, wherein each profile of the profiles corresponds to a respective threshold value;
evaluating the profiles; and
selecting a specified threshold value of the threshold values based on the evaluating.

17. The method of claim 16, wherein the evaluating includes determining values of a characteristic parameter of the profiles.

18. The method of claim 16, wherein the image representation is an image of the pattern captured using a metrology tool.

19. The method of claim 1, wherein the image representation is a simulated image generated using one or more simulation methods based on data of a further pattern to be printed on a substrate.

20. A non-transitory computer-readable medium having instructions recorded thereon, the instructions, when executed by a computer system, configured to cause the computer system to implement at least the method of claim 16.
